(19) United States
(12) Patent Application Publication
(10) Pub. No.: US 2012/0230001 A1
(43) Pub. Date: Sep. 13, 2012

(54) ELECTRONIC DEVICE, PORTABLE ELECTRONIC TERMINAL, AND METHOD OF MANUFACTURING ELECTRONIC DEVICE

(75) Inventors: Tetsuya TAKAHASHI, Kawasaki (JP); Kenji KOBAE, Kawasaki (JP); Shuichi TAKEUCHI, Kawasaki (JP); Yoshiyuki SATOH, Kawasaki (JP); Kimio NAKAMURA, Kawasaki (JP)

(73) Assignee: FUJITSU LIMITED, Kawasaki-shi (JP)

(21) Appl. No.: 13/348,935

(22) Filed: Jan. 12, 2012

(30) Foreign Application Priority Data
Mar. 7, 2011 (JP) 2011-049663

(51) Int. Cl. H05K 7/10; H05K 3/30

(52) U.S. Cl. 361/808; 29/832

(57) ABSTRACT

An electronic device includes an interposer, a first chip being mounted on a first surface of the interposer, the first chip having a first surface facing the first surface of the interposer and a second surface opposite to the first surface of the first chip, a second chip being mounted on a second surface of the interposer opposite to the first surface of the interposer, the second chip having a first surface facing the second surface of the interposer and a second surface opposite to the first surface of the second chip, a first metal plate being connected to the second surface of the first chip, a second metal surface being provided over the second surface of the second chip, and a via penetrating through the interposer and connected to the first metal plate and the second metal plate.

### CROSS-REFERENCE TO RELATED APPLICATION

This application is based upon and claims the benefit of priority of the prior Japanese Patent Application No. 2011-49663, filed on Mar. 7, 2011, the entire contents of which are incorporated herein by reference.

### FIELD

The embodiment discussed herein is an electronic device, a portable electronic terminal, and a method of manufacturing the electronic device.

### BACKGROUND

Hitherto, there is known a multichip module in which a CPU (Central Processing Unit) chip is mounted to an upper surface of a circuit board by flip-chip bonding, and a SRAM (Static Random Access Memory) chip is mounted to a lower surface of the circuit board by flip-chip bonding. The CPU chip and the SRAM chip mounted to the circuit board are connected to a heat sink or a heat conducting plate through a heat conducting block.

Also, there is known a multichip module in which a CPU chip is mounted to an upper surface of a circuit board by flip-chip bonding, and an SRAM chip is mounted to a lower surface of the circuit board by die bonding. The CPU chip mounted to the circuit board is connected to a heat sink through a heat conducting block, and the SRAM chip is connected to a heat conducting plate through a heat conducting block that is connected to the circuit board. Japanese Patent Laid-open Publication No. 08-078618 is an example of related art.

With the recent progress in size reduction of a device incorporated in, e.g., a portable telephone terminal or a small digital camera, the size of a known electronic device, such as a multichip module, has been reduced more and more.

Chip-on-chip mounting for directly bonding chips, such as a CPU and a memory, to each other is proposed as a method for reducing the size of an electronic device. However, the chip-on-chip mounting requires both the chips to have structures dedicated for wiring connections, and versatility of the chips degrades.

For that reason, flip-chip mounting of the type mounting chips to both sides of an interposer is used in many of electronic devices incorporated in portable electronic terminals, such as portable telephone terminals and small digital cameras. That type of flip-chip mounting enables wirings between the chips to be rewired with the interposer, thus resulting in higher versatility of the chips.

However, because the coefficient of linear expansion differs between the chip, e.g., the CPU or the memory, and the interposer, warping may occur in the chip and the interposer when the chip and the interposer are heated and then cooled in a manufacturing process of the electronic device. Similar warping may also occur with cure shrinkage of an underfill that is applied between the chip, e.g., the CPU or the memory, and the interposer.

If warping occurs in the chip and the interposer, the chip or a mold resin may be damaged, for example, when the chip is packaged with the mold resin.

The damage of the chip or the mold resin reduces reliability of the electronic device.

### SUMMARY

According to an aspect of the invention, an electronic device includes an interposer having a first surface and a second surface opposite to the first surface, a first chip being mounted on the first surface of the interposer, the first chip having a first surface facing the first surface of the interposer and a second surface opposite to the first surface of the first chip, a second chip being mounted on the second surface of the interposer, the second chip having a first surface facing the second surface of the interposer and a second surface opposite to the first surface of the second chip, a first metal plate being connected to the second surface of the first chip, the first metal having a first surface connected to the second surface of the first chip and a second surface opposite to the first surface of the first metal, a second metal surface being provided over the second surface of the second chip, and a first via penetrating through the interposer and connected to the first metal plate and the second metal plate.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 illustrates a sectional structure of an electronic device as a comparative example;

FIGS. 2A and 2B illustrate a portable electronic terminal including an electronic device according to an embodiment; specifically, FIG. 2A is a perspective view, illustrating the inside in a seeing-through way, and FIG. 2B illustrates a mother board included in the portable electronic terminal;

FIG. 3 illustrates a sectional structure of the electronic device according to the embodiment;

FIG. 4 illustrates a structure of the electronic device according to the embodiment, as viewed from above, in a seeing-through way;

FIG. 5 illustrates heat dissipating paths in the electronic device according to the embodiment;

FIGS. 6A to 6D illustrate successive manufacturing steps for the electronic device according to the embodiment;

FIGS. 7A to 7C illustrate successive manufacturing steps for the electronic device according to the embodiment;

FIGS. 8A to 8C illustrate successive manufacturing steps for the electronic device according to the embodiment; and

FIGS. 9A to 9C illustrate successive manufacturing steps for the electronic device according to the embodiment.

### DESCRIPTION OF EMBODIMENT

A preferred embodiment of an electronic device, a portable electronic terminal, and a method of manufacturing the electronic device will be described below.

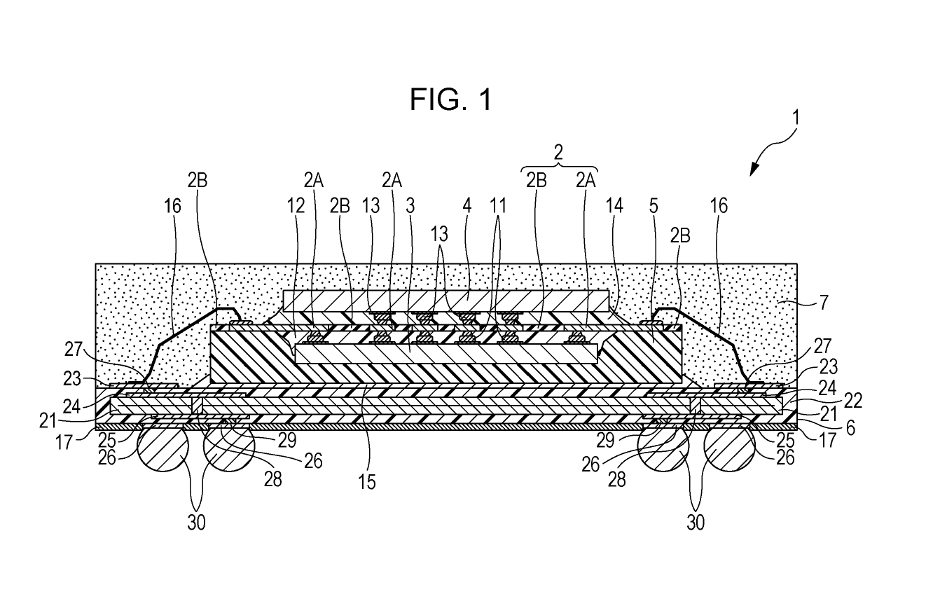

Prior to describing the electronic device, the portable electronic terminal, and the method of manufacturing the electronic device according to the present invention, an electronic device as a comparative example and problems therewith are described with reference to FIG. 1.

FIG. 1 illustrates a sectional structure of an electronic device 1 as the comparative example.

The electronic device 1 as the comparative example includes an interposer 2, a chip 3, a chip 4, a mold resin portion 5, a package board 6, and a mold resin portion 7.

The interposer 2 is a single-layer interposer including wiring portions 2A and insulating portions 2B, which are disposed on the same plane. The interposer 2 is of the so-called double-sided mounting type in which the chip 3 is mounted to one surface (lower surface in FIG. 1) and the chip 4 is mounted to the other surface (upper surface in FIG. 1). The wiring portions 2A are formed of metal wires of copper, for example, and the insulating portions 2B are made of an insulating organic material, for example. Patterns of the wiring portions 2A are designed in match with the positions, the shapes, etc. of terminals of the chips 3 and 4.

The chip 3 is, for example, a chip including an arithmetic processing unit that executes arithmetic processing, such as a CPU (Central Processing Unit) or an MPU (Micro Processing Unit).

The chip 3 is mounted to the one surface (lower surface in FIG. 1) of the interposer 2 by flip-chip bonding and is connected to the wiring portions 2A through bumps 11. For example, gold balls can be used as the bumps 11.

An underfill 12 is applied between the chip 3 and the interposer 2. The underfill 12 serves to reinforce connection strength between the chip 3 and the interposer 2. For example, a thermosetting epoxy resin may be used as the underfill 12.

While FIG. 1 illustrates a state where one chip 3 is mounted to the interposer 2, a plurality of chips 3 may be mounted to the interposer 2.

The chip 4 is, for example, a memory chip, such as a DRAM (Dynamic Random Access Memory), a SRAM (Static Random Access Memory), or a FRAM (Ferroelectric Random Access Memory). The chip 4 is mounted to the other surface (upper surface in FIG. 1) of the interposer 2 by the flip-chip bonding and is connected to the wiring portions 2A through bumps 13. For example, gold balls can be used as the bumps 13.

An underfill 14 is applied between the chip 4 and the interposer 2. The underfill 14 serves to reinforce connection strength between the chip 4 and the interposer 2. For example, a thermosetting epoxy resin may be used as the underfill 14.

While FIG. 1 illustrates a state where one chip 4 is mounted to the interposer 2, a plurality of chips 4 may be mounted to the interposer 2.

The mold resin portion 5 is a resin portion molded to cover side surfaces and a lower surface of the chip 3, and it serves to protect the chip 3. For example, a thermosetting epoxy resin may be used as the mold resin portion 5.

The package board 6 includes a core member 21, a resin portion 22, wiring portions 23, 24, 25 and 26, and vias 27, 28 and 29.

The core member 21 is made of, e.g., glass fibers. The wiring portion 24 is formed on one surface (lower surface in FIG. 1) of the core member 21, and the wiring portion 25 is formed on the other surface (lower surface in FIG. 1) of the core member 21. The wiring portion 24 and the wiring portion 25 are connected to each other through the via 28 that penetrates through the core member 21 in the direction of thickness thereof.

The resin portion 22 is formed to cover the core member 21. For example, an epoxy resin may be used as the resin portion 22. The wiring portion 23 is formed on one surface (upper surface in FIG. 1) of the resin portion 22, and the wiring portion 26 is formed on the other surface (lower surface in FIG. 1) of the resin portion 22. The wiring portion 23 is connected to the wiring portion 24 through the via 27, and the wiring portion 26 is connected to the wiring portion 25 through the via 29.

The wiring portions 23 to 26 are formed, as described above, on both the surfaces and between layers of the package board 6. The wiring portions 23 to 26 are each formed, for example, by patterning a copper foil. The package board 6, illustrated in FIG. 1, is a multiplayer board including the wiring portions 23 to 26 in four layers.

The vias 27 to 29 are formed, as described above, through the core member 21 or the resin portion 22 of the package board 6 in the direction of thickness thereof for connection between corresponding twos of the wiring portions 23 to 26. The vias 27 to 29 are each fabricated, for example, by forming a copper foil on an inner surface of a hole that is formed to penetrate through the core member 21 or the resin portion 22 in the direction of thickness thereof.

The chips 3 and 4 are mounted to the package board 6 by fixing the mold resin portion 5 to the upper surface of the package board 6 with an adhesive 15 in the state where the chips 3 and 4 are mounted to both the surfaces of the interposer 2 and the chip 3 is covered with the mold resin portion 5.

In the state after the mounting to the package board 6, an end of a bonding wire 16 is connected to the wiring portion 2A of the interposer 2, and the other end of the bonding wire 16 is connected to the wiring portion 23.

In the state where the wiring portions 2A of the interposer 2 and the wiring portions 23 of the package board 6 are connected to each other by the bonding wires 16, the mold resin portion 7 is formed to cover an upper surface of the chip 4, side surfaces of the mold resin portion 5, and an upper surface of the package board 6. For example, a thermosetting epoxy resin may be used as the mold resin portion 7.

A solder resist 17 is formed in a lower surface of the package board 6 except for the wiring portion 26, and a solder ball 30 is mounted to the wiring portion 26. For example, a thermosetting epoxy resin coating may be used as the solder resist 17.

Because the interposer 2 includes the wiring portions 2A made of copper and the insulating portions 2B made of the organic material while the chips 3 and 4 includes elements made of, e.g., silicon, such as the CPU, the MPU, and the memory, the coefficient of linear expansion of the interposer 2 is larger than that of each of the chips 3 and 4.

It is here assumed, by way of example, that the chip 3 is first mounted to the interposer 2 and the chip 4 is then mounted the interposer 2.

In that case, if the chip 3 is connected to the interposer 2 through the bumps 11 by heating the interposer 2, the chip 3, the bumps 11, and the underfill 12, stresses are interactively generated in the interposer 2 and the chip 3 with the difference in the coefficient of linear expansion therebetween when cooled. The generated stresses acts to convex a central portion of the interposer 2, whereby the interposer 2 and the chip 3 are warped.

Similar warping may also occur with thermal shrinkage of the underfill 12 in some cases.

The warping of the interposer 2 and the chip 3 may cause a connection failure between the interposer 2 and the chip 3, or cracking of the mold resin portion 5 or 7 when the mold resin portion 5 or 7 is formed in a later step.

Also, when the second chip 4 is mounted to the wiring portions 2A of the interposer 2 in the state where the interposer 2 is warped as mentioned above, some connections between the wiring portions 2A and the chip 4 through the bumps 13 may be unsatisfactorily established and reliability in mounting of the chip 4 may be reduced in some cases.

Considering heat dissipation from the chips 3 and 4, the chip 3 executing arithmetic processing, such as the CPU or the MPU, generates a larger quantity of heat than the chip 4 not executing arithmetic processing, such as the memory.

The chip 3 is covered with the interposer 2 and the underfill 12 on the upper side, and with the mold resin portion 5 on the lower side.

Here, the thermal conductivity of silicon is 148 W/mK, and the thermal conductivity of the epoxy resin used for the mold resin portion 5 and the underfill 12 is about 0.4 W/mK. In other words, the thermal conductivity of the resin is about 1/370 of that of silicon.

In the electronic device 1 of the comparative example, therefore, it is not so expected that heat generated by the chip 3 is dissipated through the mold resin portion 5 and the underfill 12. Thus, a path for heat dissipation from the chip 3 is not sufficiently obtained.

Another problem is that, although the chip 4 generates a smaller quantity of heat than the chip 3, a path for heat dissipation from the chip 4 is also not sufficiently obtained when the chip 4 generates heat.

The above-described problem of the heat dissipation path is more serious particularly when a silicon substrate of, e.g., the CPU or the MPU is exposed to a rear surface (lower surface in FIG. 1) of the chip 3, or when a silicon substrate of the memory is exposed to a rear surface (upper surface in FIG. 1) of the chip 4.

The above-described drawbacks, such as damage of the chip, reduction in mounting reliability of the chip, and insufficient heat dissipation paths, reduce reliability of the electronic device.

Thus, the electronic device 1 of the comparative example has the problem that reliability of the electronic device degrades with, e.g., the damage of the chip, the reduction in mounting reliability of the chip, and the insufficient heat dissipation paths.

In view of the foregoing points, an embodiment described below is intended to provide a portable electronic terminal free from the above-described problems. An electronic device, a portable electronic terminal, and a method of manufacturing the electronic device, according to the embodiment, will be described below.

### Embodiment

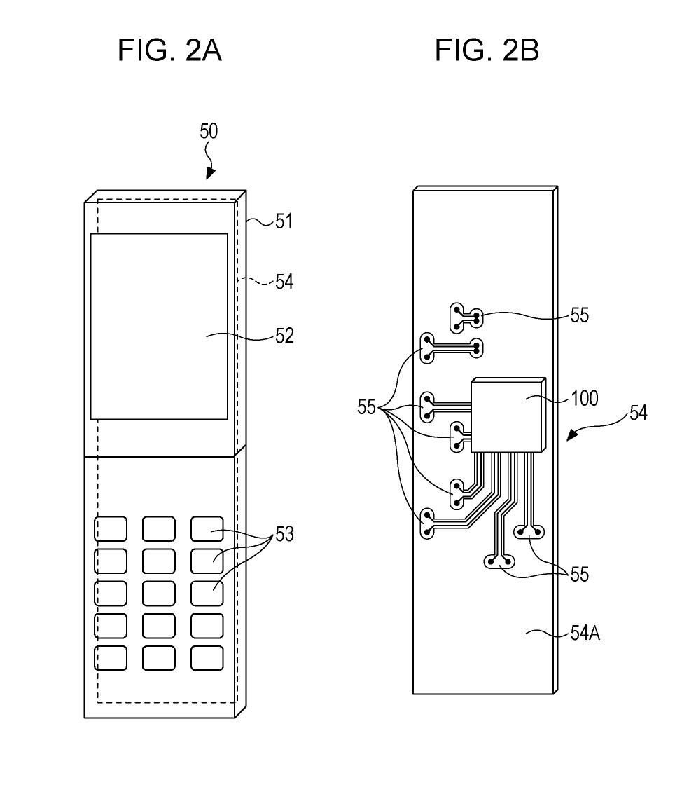

FIGS. 2A and 2B illustrate a portable electronic terminal (portable telephone terminal 50) including an electronic device 100 according to the embodiment. Specifically, FIG. 2A is a perspective view, illustrating the inside in a seeing-through way, and FIG. 2B illustrates a mother board 54 included in the portable telephone terminal 50.

In the following description of the electronic device 100 according to the embodiment, the same or equivalent components to those in the electronic device 1 of the comparative example are denoted by the same reference symbols and description of those components is omitted.

As illustrated in FIG. 2A, a display unit 52 and an operating unit 53 are disposed in an outer surface of a housing 51 of the portable telephone terminal 50, and a mother board 54, denoted by a dotted line, is contained in the housing 51.

Here, the portable telephone terminal 50 is one example of the portable electronic terminal, and the mother board 54 is one example of an electronic circuit board.

The housing 51 is made of a resin or a metal, and it has openings in which the display unit 52 and the operating unit 53 are disposed. The display unit 52 may be, for example, a liquid crystal panel capable of displaying characters, numerals, images, etc. The operating unit 53 includes not only a ten-key numerical pad, but also various selection keys for optionally selecting functions of the portable telephone terminal 50. The portable telephone terminal 50 may include attachments, such as a near field communication device (e.g., an infrared communication device or a communication device for electronic money) and a camera.

The mother board 54, illustrated in FIG. 2B, is formed of, e.g., FR4 (glass fabric substrate impregnated with epoxy resin), and wiring portions 55 are formed on a surface 54A of the mother board 54 by patterning a copper foil. The wiring portions 55 serve as transmission paths for various signals necessary for driving the electronic device. The wiring portions 55 are patterned, for example, by an etching process using a resist.

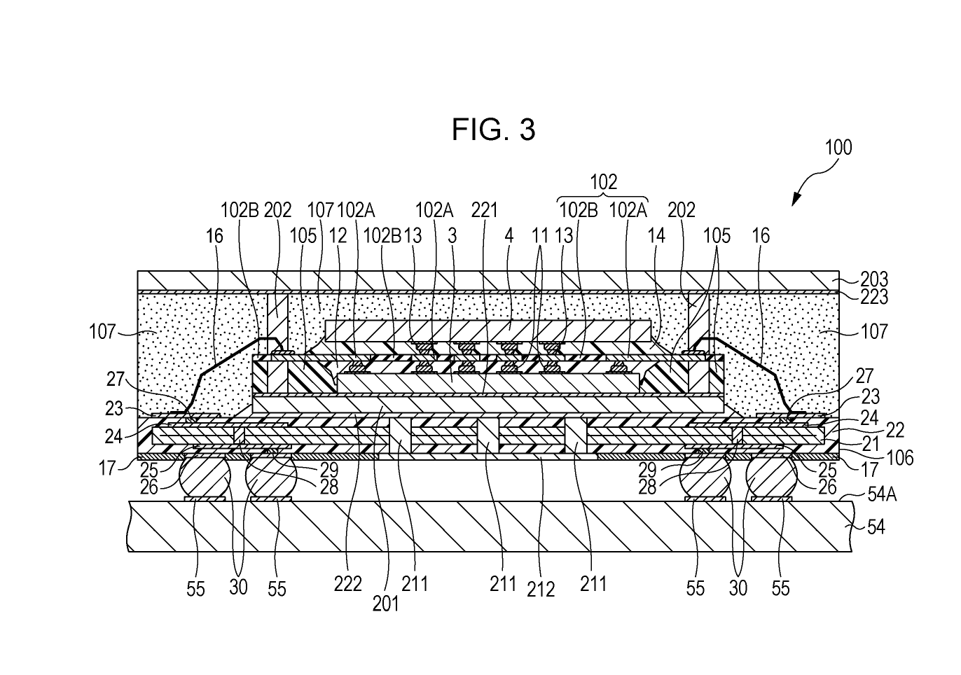

The electronic device 100 for executing processing for communications, such as conversation, electronic mails, and the Internet, in the portable telephone terminal 50 is connected to the wiring portions 55. The electronic device 100 is connected to the wiring portions 55 through solder balls 30 (see FIG. 3), whereby it is mounted to the mother board 54.

The FR4 used as the mother board 54 generally includes a plurality of insulating layers stacked one above another, and copper foils in the patterned form between adjacent two of the insulating layers (i.e., at interlayer positions), on an uppermost surface of a stacked structure, and on a lowermost surface of the stacked structure.

The electronic device 100 may be mounted in plural to the mother board 54, and the electronic device 100 may be formed on a rear surface of the mother board 54.

The mother board 54 may be made of a substrate other than the FR4 insofar as the substrate is made of a dielectric and the wiring portions 55 can be formed on the substrate for mounting of a circuit.

The wiring portions 55 may be made of a metal (e.g., aluminum (Al)) other than copper (Cu) insofar as the metal produces a small power loss and has a high electrical conductivity.

While FIGS. 2A and 2B illustrate the portable telephone terminal 50 as one example of the portable electronic terminal, the portable electronic terminal is not limited to the portable telephone terminal 50 and it may be, e.g., a smartphone terminal, a digital camera, a video camera, or a game machine.

The electronic device 100 according to the embodiment will be described below with reference to FIG. 3.

FIG. 3 illustrates a sectional structure of the electronic device 100 according to the embodiment.

The electronic device 100 according to the embodiment includes a metal plate 201, vias 202, and a metal plate 203 in addition to an interposer 102, a chip 3, a chip 4, a mold resin portion 105, a package board 106, and a mold resin portion 107.

The interposer 102 is basically the same as the interposer 2 in the comparative example, but it differs from the interposer 2 in the comparative example in that the vias 202 extend through the insulating portions 102B. Because the other structure of the interposer 102 is similar to that of the interposer 2 in the comparative example, description of the interposer 102 is incorporated here by reference to the description of the interposer 2 in the comparative example, and the following description is made primarily on different points between both the interposers.

The chip 3 is similar to the chip 3 in the comparative example and is, for example, a chip including an arithmetic processing unit that executes arithmetic processing, such as a CPU or an MPU. The chip 3 is mounted to one surface (lower surface in FIG. 3, corresponding to first surface in claims) of the interposer 102 by flip-chip bonding and is connected to wiring portions 102A through bumps 11. An underfill 12 is applied between the chip 3 and the interposer 102.

Here, a front surface (active surface) of the chip 3 is a surface (upper surface in FIG. 3, corresponding to first surface in claims) on the side connected to the interposer 102, and a rear surface (backside) of the chip 3 is a surface (lower surface in FIG. 3, corresponding to second surface in claims) on the side opposite to the front surface.

The chip 3 is mounted to the metal plate 201. The chip 3 and the metal plate 201 are connected to each other with an electroconductive adhesive 221 interposed therebetween. The underfill 12 is applied between the chip 3 and the interposer 102. An electroconductive paste may be used instead of the electroconductive adhesive 221. One example of the electroconductive paste is a silver paste.

It is to be noted that the chip 3 is one example of a first chip, and the metal plate 201 is one example of a first metal plate. One surface (upper surface in FIG. 3, corresponding to first surface in claims) of the metal plate 201 is connected to the rear surface of the chip 3 as the first chip. While FIG. 3 illustrates a state where one chip 3 is mounted to the interposer 102, a plurality of chips 3 may be mounted to the interposer 102.

The chip 4 is similar to the chip 4 in the comparative example and is, for example, a memory chip, such as a DRAM, a SRAM, or a FRAM. The chip 4 is mounted to the other surface (upper surface in FIG. 3, corresponding to second surface in claims) of the interposer 102 by the flip-chip bonding through bumps 13. An underfill 14 is applied between the chip 4 and the interposer 102. The chip 4 is supplied with electric power from the chip 3 through the wiring portions 102A of the interposer 102.

Here, a front surface (active surface) of the chip 4 is a surface (lower surface in FIG. 3, corresponding to first surface in claims) on the side connected to the interposer 102, and a rear surface (backside) of the chip 4 is a surface (upper surface in FIG. 3, corresponding to second surface in claims) on the side opposite to the front surface.

While FIG. 3 illustrates a state where one chip 4 is mounted to the interposer 102, a plurality of chips 4 may be mounted to the interposer 102.

The mold resin portion 105 is a resin portion molded on the metal plate 201 to cover side surfaces of the chip 3, and it serves to protect the chip 3. The mold resin portion 5 is similar to the mold resin portion 5 in the comparative example except that the former covers the side surfaces of the chip 3 without covering a bottom surface thereof, and that the vias 202 are formed in the mold resin portion 105. For example, a thermosetting epoxy resin may be used as the mold resin portion 105.

The package board 106 includes a core member 21, a resin portion 22, wiring portions 23, 24, 25 and 26, and vias 27, 28 and 29 similarly to the package board 6 in the comparative example, but the package board 106 differs from the package board 6 in the comparative example in that the former includes vias 211 and a radiator plate 212.

The vias 211 are formed to penetrate through the package board 106 in the direction of thickness thereof and are filled with, e.g., a Ni plating, a Cu plating, or an Ag paste. The vias 211 are each connected at its upper end to the metal plate 201 through an electroconductive adhesive and is connected at its lower end to the radiator plate 212. An electroconductive paste may be used instead of the electroconductive adhesive. One example of the electroconductive paste is a silver paste.

The package board 106 is connected to the wiring portions 55 of the mother board 54 through the solder balls 30. As a result, the electronic device 100 according to the embodiment is mounted to the mother board 54.

In the state where the package board 106 is connected to the wiring portions 55 of the mother board 54 through the solder balls 30, there is a gap between the package board 106 and the mother board 54. Thus, the radiator plate 212 is positioned to face the upper surface 54A of the mother board 54 with the gap interposed therebetween.

The radiator plate 212 is a metal plate disposed at the under surface (corresponding to second surface in claims) of the package board 106 for heat radiation and is connected to lower ends of the vias 211. The radiator plate 212 may be, e.g., a plate made of aluminum or copper, an aluminum foil, or a copper foil. The radiator plate 212 may be formed, for example, by vapor deposition, or by bonding a sheet in the form of a thin plate to a lower surface of the package board 106 and connecting the sheet to the vias 211 with, e.g., an electroconductive adhesive. An electroconductive paste may be used instead of the electroconductive adhesive. One example of the electroconductive paste is a silver paste.

The mold resin portion 107 is similar to the mold resin portion 7 in the comparative example except that the vias 202 are formed in the mold resin portion 107, and that the metal plate 203 is disposed on an upper surface of the mold resin portion 107.

The metal plate 201 is a metal plate having a rectangular shape in a plan view. The chip 3 is fixed to an upper surface of the metal plate 201 in a central portion thereof with an electroconductive adhesive 221, and the lower ends of the vias 202 are connected to the upper surface of the metal plate 201 near four corners thereof. Further, the other surface (lower surface in FIG. 3, corresponding to second surface in claims) of the metal plate 201 is fixed to an upper surface (corresponding to first surface in claims) of the package board 106 with an electroconductive adhesive 222.

The metal plate 201 is disposed with intent to suppress warping of the chip 3 and the interposer 102 against stresses that are interactively generated in the chip 3 and the interposer 102 in the state where the chip 3 and the interposer 102 are connected to each other.

Further, the metal plate 201 is disposed with intent to dissipate heat generated from the chip 3. For the heat dissipation, the metal plate 201 is connected to the metal plate 203 through the vias 202.

The metal plate 201 may be made of, e.g., nickel (Ni), copper (Cu), gold (Au), silver (Ag), iron (Fe), chromium (Cr), aluminum (Al), titanium (Ti), magnesium (Mg), silicon (Si), molybdenum (Mo), or tungsten (W).

When the metal plate 201 is made of an alloy, the metal plate 201 may be formed by using an alloy containing one or more of Ni, Cu, Au, Ag, Fe, Cr, Al, Ti, Mg, Si, Mo, or W.

The metal plate 201 is formed to have three-dimensional sizes (length, width and thickness), density, and other properties, which are necessary to provide strength capable of sufficiently suppressing the warping that may occur in the chip 3 and the interposer 102 with the stresses that may be interactively generated in the chip 3 and the interposer 102.

The vias 202 are connected to the upper surface of the metal plate 201 after penetrating through the mold resin portion 107, the interposer 102, and the mold resin portion 105.

The vias 202 are each formed, for example, by forming a hole penetrating through the mold resin portion 107, the interposer 102, and the mold resin portion 105 and reaching the upper surface of the metal plate 201, and then filling a nickel (Ni) plating, a copper (Cu) plating, or a silver (Ag) paste in the hole. The hole penetrating through the mold resin portion 107, the interposer 102, and the mold resin portion 105 and reaching the upper surface of the metal plate 201 may be formed, for example, with a machining process using a drill, or an etching process with laser irradiation using a mask.

The metal plate 203 is fixedly disposed and covers respective upper surfaces of the mold resin portion 107 and the vias 202. The metal plate 203 is connected to the respective upper surfaces of the mold resin portion 107 and the vias 202 with an electroconductive adhesive 223.

The metal plate 203 may be made of, e.g., nickel (Ni), copper (Cu), gold (Au), silver (Ag), iron (Fe), chromium (Cr), aluminum (Al), titanium (Ti), magnesium (Mg), silicon (Si), molybdenum (Mo), or tungsten (W).

When the metal plate 203 is made of an alloy, the metal plate 203 may be formed by using an alloy containing one or more of Ni, Cu, Au, Ag, Fe, Cr, Al, Ti, Mg, Si, Mo, or W.

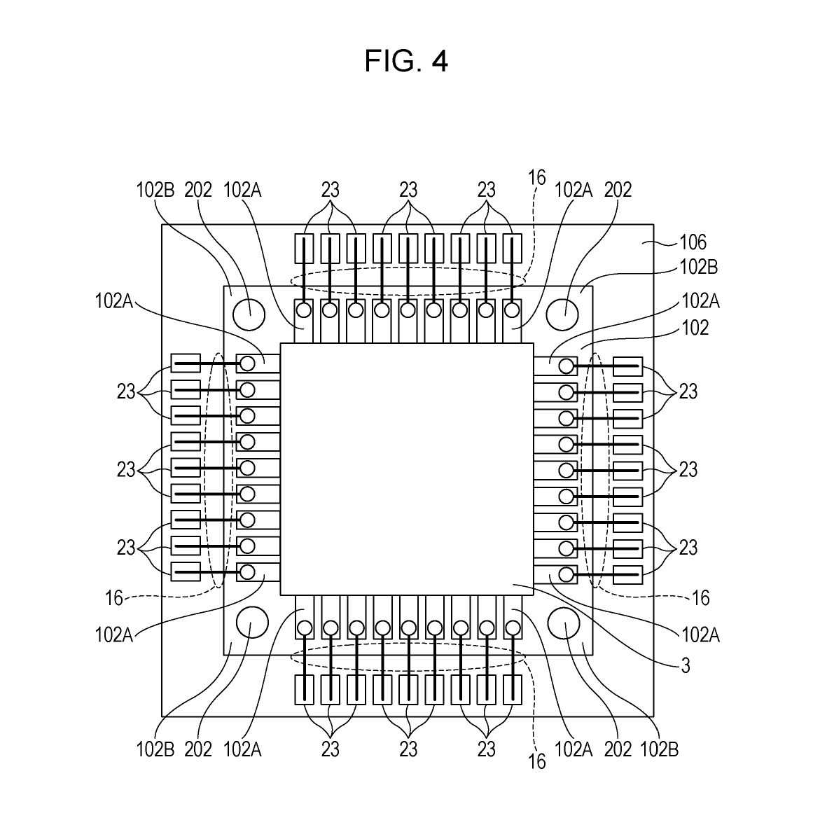

The structure of the electronic device 100 according to the embodiment, as viewed from above, will be described below with reference to FIG. 4.

FIG. 4 illustrates the structure of the electronic device 100 according to the embodiment, as viewed from above, in a seeing-through way. Specifically, FIG. 4 illustrates the structure of the electronic device 100, in a plan view, with omission of the mold resin portion 107 and the metal plate 203.

When viewing the electronic device 100 from above, as illustrated in FIG. 4, the chip 3 is positioned at a center, the interposer 102 is positioned on the outer side of the chip 3, and the package board 106 is positioned on the outer side of the interposer 102.

In one example illustrated in FIG. 4, each of the chip 3, the interposer 102, and the package board 106 is substantially square in a plan view.

The interposer 102 has a total of 36 wiring portions 102A which are positioned along four sides of the chip 3 as viewed from above. Those 36 wiring portions 102A are arranged in units of 9 along each of the four sides of the chip 3.

Further, the vias 202 are formed to penetrate through the insulating portions 102B at four corners of the interposer 102. The reason why the vias 202 are formed to penetrate through the insulating portions 102B at the four corners of the interposer 102 resides in that it is harder to form the wiring portions 102A at the four corners of the interposer 102 than in regions except for the four corners, and that the vias 202 can be formed to penetrate through the insulating portions 102B without substantially changing the positions of the wiring portions 102A.

Thus, of the upper surface of the interposer 102 which appears on the outer side of the chip 3 as viewed from above, regions other than the 36 wiring portions 102A and the vias 202 represent upper surfaces of the insulating portions 102B.

The package board 106 is disposed such that it appears to externally surround four sides of the interposer 2 as viewed from above. On the upper surface of the package board 106, a total of 36 wiring portions 23 are arranged along the four sides of the interposer 102. Those 36 wiring portions 23 are arranged in units of 9 along each of the four sides of the interposer 102.

The wiring portions 102A on the interposer 102 and the wiring portions 23 on the package board 106 are connected to each other by bonding wires 16.

While FIG. 4 illustrates the embodiment in which the vias 202 penetrate through the insulating portions 102B at the four corners of the interposer 102, the vias 202 may be formed to penetrate through the insulating portions 102B at positions other than the four corners of the interposer 102. Also, the number of the vias 202 is not limited to four insofar as at least one via 202 is formed.

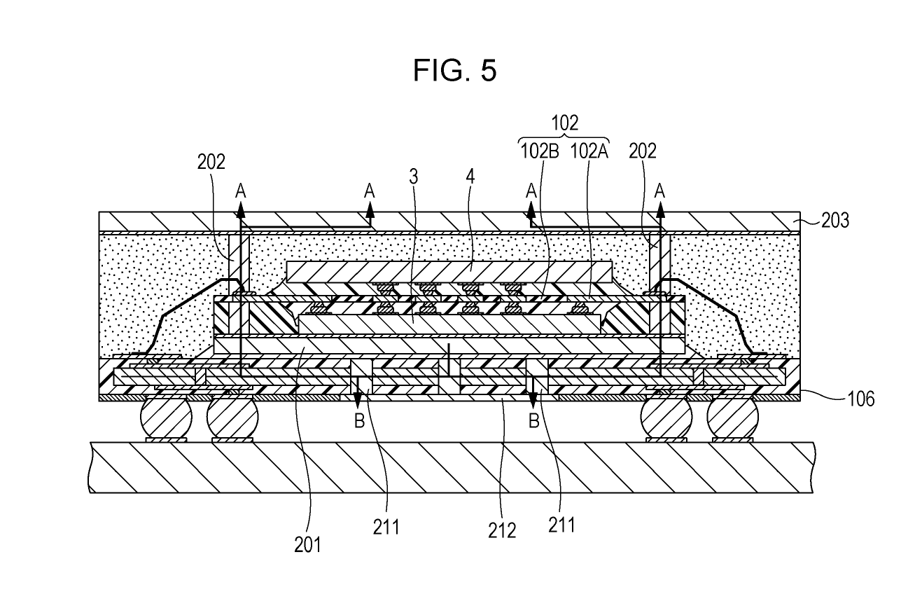

Heat dissipation paths in the electronic device 100 according to the embodiment will be described below with reference to FIG. 5.

FIG. 5 illustrates the heat dissipating paths in the electronic device 100 according to the embodiment. In FIG. 5, only some of the components of the electronic device 100 are denoted by the reference symbols for clearer representation of arrows that indicate the heat dissipating paths.

In the electronic device 100 according to the embodiment, the heat generated from the chip 3 is dissipated through the metal plate 201, the vias 202, and the metal plate 203. Thus, the heat dissipating paths in this case are given by paths extending from the chip 3 and passing through the metal plate 201, the vias 202, and the metal plate 203 as indicated by arrows A.

The heat generated from the chip 3 is further dissipated through a path passing through the metal plate 201, the vias 211, and the radiator plate 212. The heat dissipating paths in this case are indicated by arrows B.

The chip 4, such as the memory chip, generates a smaller quantity of heat than the chip 3 including the arithmetic processing unit, such as the CPU or the MPU. However, because the chip 4 is connected to the heat dissipating paths A and B through the interposer 102 and the chip 3, the heat dissipating paths for the chip 4 are also ensured.

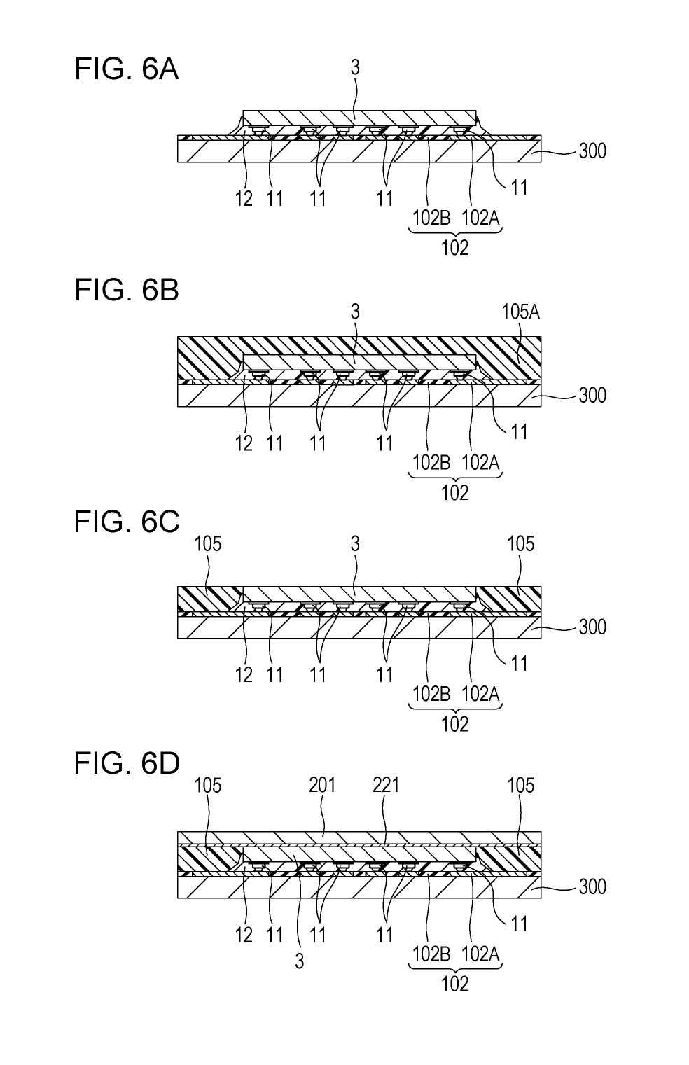

Manufacturing steps for the electronic device 100 will be described below with reference to FIGS. 6A to 6D, 7A to 7C, 8A to 8C, and 9A to 9C.

FIGS. 6A to 6D, 7A to 7C, 8A to 8C, and 9A to 9C illustrate successive manufacturing steps for the electronic device 100 according to the embodiment.

In the state illustrated in FIG. 6A, the components are illustrated in a vertically reversed relation to the state illustrated in FIGS. 2A and 2B.

First, as illustrated in FIG. 6A, the chip 3 including the bumps 11 attached thereto is mounted to the interposer 102 in a state where the interposer 102 is formed on a surface of a support base 300 and where the material for the underfill 12 is coated on the interposer 102.

The interposer 102 is formed on a copper plate surface by processing the surface of one copper plate and by partially forming the insulating portions 102B made of the organic material on the processed surface of the copper plate. The support base 300 corresponds to a portion that is left after removing the wiring portions 102A and the insulating portions 102B of the interposer 102 from the copper plate.

In that state, the support base 300, the interposer 102, the bumps 11, the material for the underfill 12, and the chip 3 are heated for thermal curing of the underfill 12, while the chip 3 is pressed against the interposer 102 such that the bumps 11 are secured to the wiring portions 102A of the interposer 102.

Thereafter, the support base 300, the interposer 102, the bumps 11, the underfill 12, and the chip 3 are cooled.

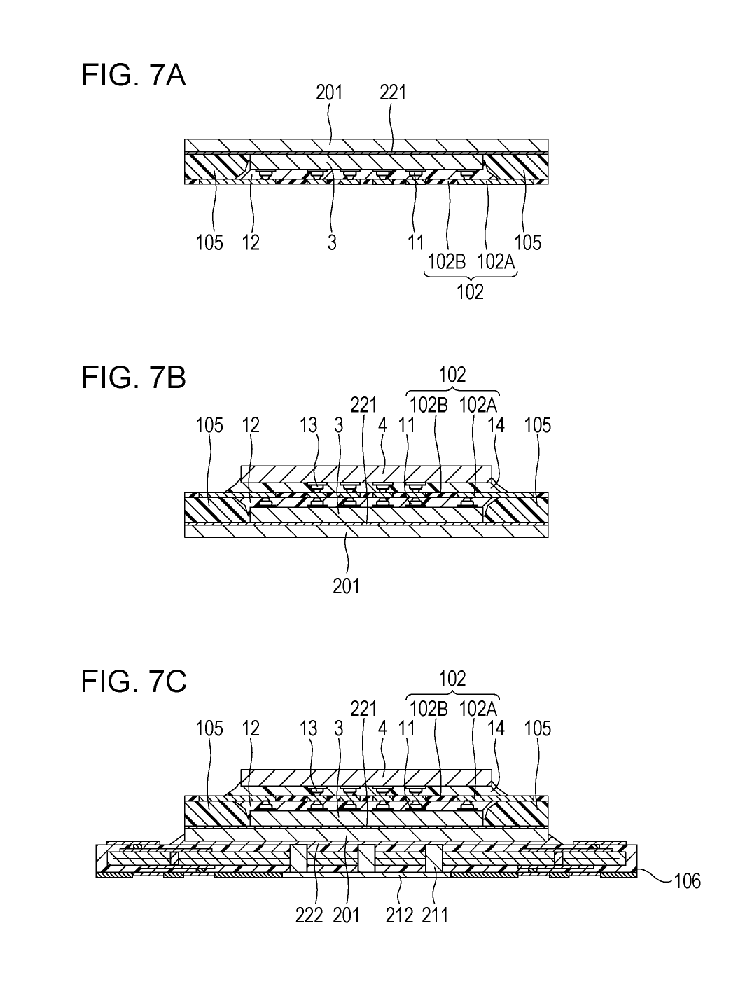

Here, the support base 300 is employed as a jig for fixedly holding the interposer 102 in the steps illustrated in FIGS. 6A to 6D, and it is removed when the manufacturing process is shifted from the step of FIG. 6D to the step of FIG. 7A.

FIG. 6A illustrates the support base 300, the interposer 102, the bumps 11, the underfill 12, and the chip 3 which correspond to one electronic device 100. In practice, however, many electronic devices 100 are fabricated at a time and are separated into individual pieces later. The separation into the individual pieces is performed between the step of FIG. 7B and the step of FIG. 7C.

In practice, therefore, the support base 300 and the interposer 102 are in the form integral with all the electronic devices 100 in the step of FIG. 6A. In an actual process, the interposer 102 before the separation into the individual pieces is formed on one large support base 300, and many chips 3 are mounted onto the interposer 102. In that state, the underfill 12 is thermally cured and the bumps 11 are connected to the wiring portions 102A of the interposer 102.

Next, as illustrated in FIG. 6B, a resin portion 105A is molded on the chip 3, the underfill 12, and the interposer 102. The resin portion 105A is molded integrally with all the electronic devices 100.

Next, as illustrated in FIG. 6C, the resin portion 105A is ground from the upper side, as viewed in FIG. 6C, until the chip 3 is exposed to the surface. The grinding may be carried out, for example, by using a grinder. With the step of FIG. 6C, an upper part of the resin portion 105A is ground down, whereby the mold resin portion 105 is completed.

Next, as illustrated in FIG. 6D, the metal plate 201 is fixed onto the chip 3 and the mold resin portion 105 with the electroconductive adhesive 221. The metal plate 201 may be in the form integral with all the electronic devices 100.

In the stage illustrated in FIG. 6D, the metal plate 201 is not yet divided into individual pieces and is integrally fixed onto the chips 3 and the mold resin portions 105 corresponding to all the electronic devices 100.

Next, as illustrated in FIG. 7A, the support base 300 is removed. When the support base 300 is made of copper, the support base 300 may be removed or peeled off by, e.g., wet etching using ferric chloride (FeCl₃).

Next, as illustrated in FIG. 7B, in a state where the interposer 102, the chip 3, and the metal plate 201 are turned upside down such that the interposer 102 is positioned on the upper side, the material for the underfill 14 is coated on the interposer 102 and the chip 4 including the bumps 13 attached thereto is mounted to the interposer 102.

In that state, the support base 300, the interposer 102, the bumps 13, the material for the underfill 14, and the chip 4 are heated for thermal curing of the underfill 14, while the chip 4 is pressed against the interposer 102 such that the bumps 13 are secured to the wiring portions 102A of the interposer 102.

Thereafter, the support base 300, the interposer 102, the bumps 13, the material for the underfill 14, and the chip 4 are cooled.

After the end of the step illustrated in FIG. 7B, the interposer 102, the mold resin portion 105, and the metal plate 201 are each divided into individual pieces by dicing.

Next, as illustrated in FIG. 7C, the metal plate 201 is connected to the upper surface of the package board 106 with the electroconductive adhesive 222.

The package board 106 is previously prepared as including the core member 21, the resin portion 22, the wiring portions 23, 24, 25 and 26, the vias 27, 28 and 29, the vias 211, and the radiator plate 212.

The package board 106 used in this step is integral with all the electronic devices 100. Thus, many devices each including the interposer 102, the mold resin portion 105, the metal plate 201, and the chips 3 and 4, the devices having been divided into individual pieces after the end of the step illustrated in FIG. 7B, are arrayed on the package board 106.

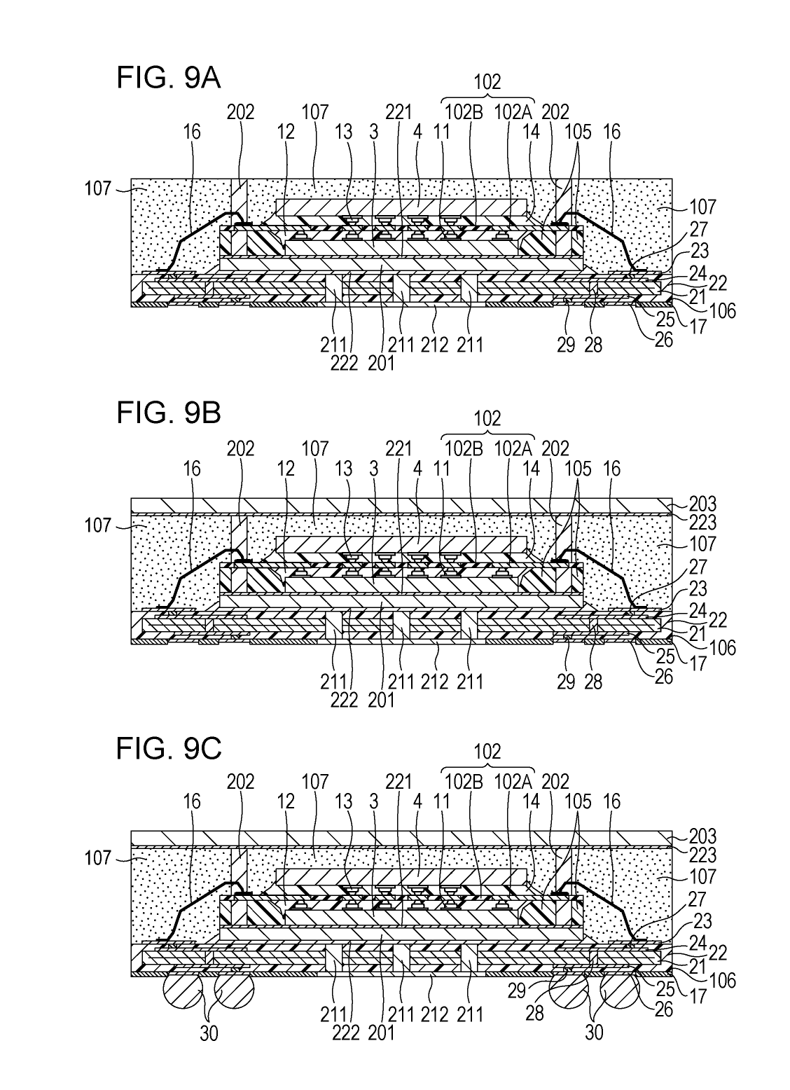

The package board 106 is divided into individual pieces by dicing after the end of the step illustrated in FIG. 9C.

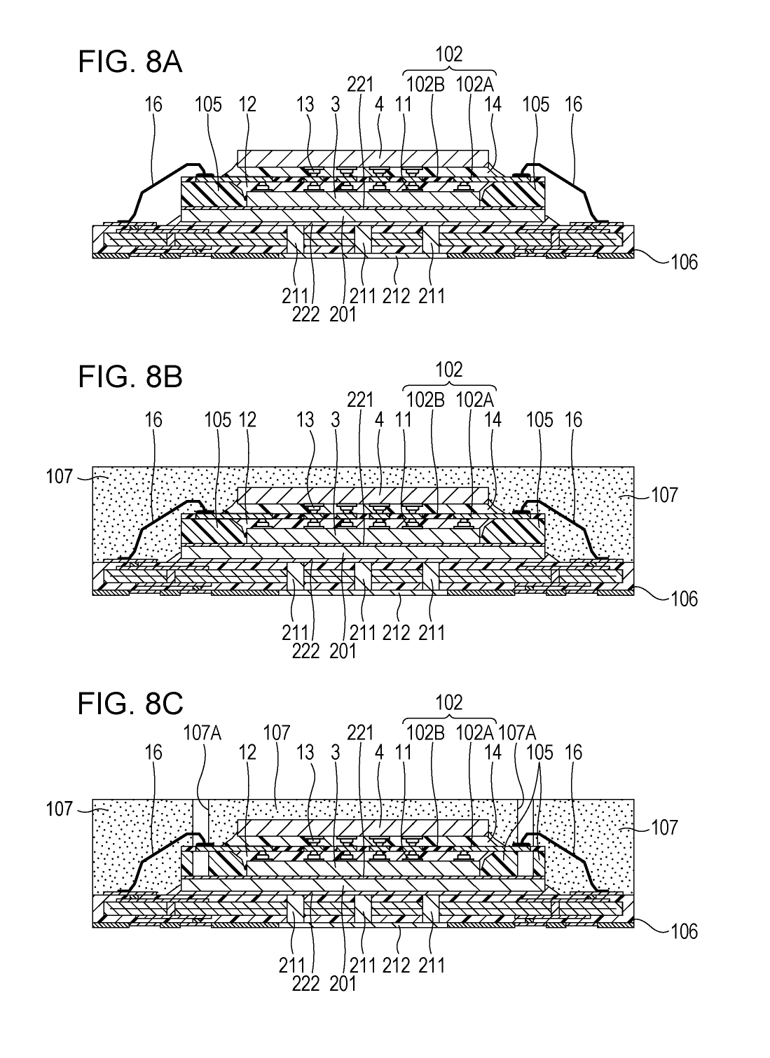

Next, as illustrated in FIG. 8A, one end of the bonding wire 16 is connected to the corresponding wiring portion 102A of the interposer 102, and the other end of the bonding wire 16 is connected to the corresponding wiring portion 23 of the package board 106. The connection of the bonding wire 16 may be performed, for example, by applying ultrasonic waves under heating.

Next, as illustrated in FIG. 8B, the mold resin portion 107 is molded on the chip 4, the bonding wires 16, the mold resin portion 105, and the package board 106. The mold resin portion 107 may be molded integrally with all the electronic devices 100, and may be divided into individual pieces by dicing that is carried out after the step illustrated in FIG. 9C.

Next, as illustrated in FIG. 8C, through holes 107A extending from the surface of the mold resin portion 107 to the upper surface of the metal plate 201 are formed. The through holes 107A are formed, as illustrated in FIG. 4, to penetrate through the insulating portions 102B at the four corners of the interposer 102 in the plan view.

The through holes 107A may be formed in the mold resin portion 107, for example, by a machining process using a drill, or an etching process with laser irradiation using a mask.

The machining process using a drill may be performed such that, after the drill has reached the surface of the metal plate 201, the drilling for the through hole 107A is stopped within the range of a thickness of the metal plate 201. Also, the etching process with laser irradiation may be performed such that the laser irradiation is stopped at the time when the through hole 107A has reached the surface of the metal plate 201.

Next, as illustrated in FIG. 9A, the vias 202 are formed by filling a metal in the through holes 107A (see FIG. 8C).

Next, as illustrated in FIG. 9B, the metal plate 203 is fixed onto the mold resin portion 107 and the vias 202 by using the electroconductive adhesive 223. The metal plate 203 may be in the form integral with all the electronic devices 100.

Finally, as illustrated in FIG. 9C, the solder balls 30 are attached to the wiring portions 26 of the package board 106. In practice, the step of FIG. 9C is carried out by attaching, in a state vertically reversed from the state of FIG. 9C, the solder balls 30 to the wiring portions 26 of the package board 106 with a reflow process.

After the end of the above-described steps, the package board 106, the mold resin portion 107, and the metal plate 203 are each divided into individual pieces by dicing, whereby the electronic device 100 illustrated in FIG. 3 is completed.

As described above, the electronic device 100 according to the embodiment includes the chips 3 and 4, which are mounted to both the sides of the interposer 102, and the metal plate 201, which is positioned under the interposer 102 and which mounts thereon the chip 3 generating a larger quantity of heat than the chip 4.

Further, the electronic device 100 according to the embodiment includes the vias 202 extending upwards from the metal plate 201 while penetrating through the interposer 102, and the metal plate 203 connected to the upper ends of the vias 202.

Therefore, the heat dissipation paths for the chip 3 generating a larger quantity of heat can be ensured in the state where the electronic device 100 is mounted to the mother board 54. Those heat dissipation paths are paths that are indicated by the arrows A in FIG. 5 and that are formed by utilizing the metal plate 203 at the top of the electronic device 100.

Accordingly, the chip 3 can be efficiently cooled.

The electronic device 100 according to the embodiment includes, in addition to the heat dissipation paths described above, the heat dissipation paths extending from the metal plate 201 and reaching the radiator plate 212, which is disposed at the underside of the package board 106, through the vias 211 penetrating through the package board 106.

Hence, the cooling efficiency of the chip 3 can be further increased.

While the embodiment has been described in connection with the electronic device 100 including the vias 211 penetrating through the package board 106 and the radiator plate 212 connected to the lower ends of the vias 211, the vias 211 and the radiator plate 212 are not always required, and the electronic device 100 may include neither the vias 211 nor the radiator plate 212 in some cases.

Whether to include the vias 211 and the radiator plate 212 in the electronic device 100 or not may be determined, for example, depending on the quantity of heat generated by the chip 3.

The chip 4 mounted to the upper side of the interposer 102 and generating a smaller quantity of heat than the chip 3 is connected to the heat dissipation paths for the chip 3 through the wiring portions 102A of the interposer 102 and then the chip 3. Therefore, the chip 4 is also efficiently cooled.

Moreover, in the electronic device 100 according to the embodiment, the chip 3 mounted to the interposer 102 is fixed to the metal plate 201 in the earlier step in the manufacturing process (see the steps subsequent to FIG. 6D).

Accordingly, the occurrence of warping can be suppressed which may be caused in the manufacturing process with, e.g., the difference in coefficient of linear expansion between the interposer 102 and the chip 3.

The reason resides in that the metal plate 201 fixed to the chip 3 serves as a reinforcing member for the chip 3 and suppress the occurrence of warping against the generation of stresses.

With the electronic device 100 according to the embodiment, therefore, it is possible to suppress damage of the electronic device 100, which may be caused by, e.g., cracking of the chip 3, the mold resin portion 105, or the mold resin portion 107, and to increase the yield in production of the electronic device 100.

Further, with the electronic device 100 according to the embodiment, since the occurrence of warping of the interposer 102 and the chip 3 is suppressed as described above, the chip 4 can be reliably mounted to the interposer 102 in a later step, and the reliability in mounting of the chip 4 can be drastically increased.

Thus, the embodiment can provide the electronic device 100, which has high radiation efficiency, which can suppress damage of the electronic device during the manufacturing, and which can increase the reliability in mounting of the chip.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present inventions has been described in detail, it should be understood that the various changes, substitutions, and alterations could be made hereto without departing from the spirit and scope of the invention.

What is claimed is:

1. An electronic device comprising:
an interposer having a first surface and a second surface opposite to the first surface;
a first chip being mounted on the first surface of the interposer, the first chip having a first surface facing the first surface of the interposer and a second surface opposite to the first surface of the first chip;
a second chip being mounted on the second surface of the interposer, the second chip having a first surface facing the second surface of the interposer and a second surface opposite to the first surface of the second chip;
a first metal plate being connected to the second surface of the first chip, the first metal having a first surface connected to the second surface of the first chip and a second surface opposite to the first surface of the first metal;
a second metal surface being provided over the second surface of the second chip; and
a first via penetrating through the interposer and connected to the first metal plate and the second metal plate.

2. The electronic device according to claim 1, wherein the first via penetrates through the interposer at one or plural corners of the interposer as viewed from above.

3. The electronic device according to claim 1, wherein the first via is formed using a Ni plating, a Cu plating, or an Ag paste.

4. The electronic device according to claim 1, further comprising:
a board configured to mount the first metal plate, the board having a first surface facing the second surface of the first metal and a second surface opposite to the first surface of the board;
a radiator plate disposed on the second surface of the substrate; and
a second via penetrating through the board and connecting the first metal plate and the radiator plate.

5. The electronic device according to claim 4, wherein the second via is formed using a Ni plating, a Cu plating, or an Ag paste.

6. The electronic device according to claim 1, wherein the first metal plate and the second metal plate are made of Ni, Cu, Au, Ag, Fe, Cr, Al, Ti, Mg, Si, Mo or W, or an alloy containing one or more of Ni, Cu, Au, Ag, Fe, Cr, Al, Ti, Mg, Si, Mo and W.

7. A portable electronic terminal comprising:
an electronic circuit board; and
an electronic device being mounted on the electronic circuit board, the electronic device including
an interposer having a first surface and a second surface opposite to the first surface;
a first chip being mounted on the first surface of the interposer, the first chip having a first surface facing the first surface of the interposer and a second surface opposite to the first surface of the first chip;
a second chip being mounted on the second surface of the interposer, the second chip having a first surface facing the second surface of the interposer and a second surface opposite to the first surface of the second chip;
a first metal plate being connected to the second surface of the first chip, the first metal having a first surface connected to the second surface of the first chip and a second surface opposite to the first surface of the first metal;
a second metal surface being provided over the second surface of the second chip; and
a first via penetrating through the interposer and connected to the first metal plate and the second metal plate.

8. A method of manufacturing an electronic device, the method comprising:
mounting a first chip to a first surface of an interposer, the first chip having a first surface facing the first surface of the interposer and a second surface opposite to the first surface of the first chip;
mounting a second chip on a second surface of the interposer opposite to the first surface of the interposer, the second chip having a first surface facing the second surface of the interposer and a second surface opposite to the first surface of the second chip;
connecting a first metal plate to the second surface of the first chip;
forming a via that penetrates through the interposer and that has a first end reaching the first metal plate; and
disposing a second metal plate over the second surface side of the second chip, the second metal plate being connected to a second end of the via.
